(19) United States
(12) Patent Application Publication
(10) Pub. No.: US 2026/0136886 A1
(43) Pub. Date: May 14, 2026

(54) POPULOUS CARRIER TAPE

(71) Applicant: TEXAS INSTRUMENTS INCORPORATED, Dallas, TX (US)

(72) Inventors: Pi-Chiang Huang, Taipi (TW); Chong Han Lim, Selangor (MY); Stanley Chout, New Taipei City (TW); Chia Wei Chang, Taoyuan City (TW); Steven Kummerl, Carrollton, TX (US)

(21) Appl. No.: 19/383,362

(22) Filed: Nov. 7, 2025

Related U.S. Application Data
(60) Provisional application No. 63/720,438, filed on Nov. 14, 2024.

(51) Int. Cl. H01L 21/683; H01L 23/00

(52) U.S. Cl. CPC H10P 72/7402; H10P 72/741; H10P 72/7428; H10W 72/0198

(57) ABSTRACT

A carrier tape comprises a carrier tape length and a carrier tape width. The carrier tape also comprises a plurality of holes spaced along the carrier tape length. The carrier tape further comprises a first cavity and a second cavity. The first cavity and the second cavity are spaced along the carrier tape width.

This application claims priority to provisional application 63/720,438, filed Nov. 14, 2024, the contents of which are herein incorporated by reference in its entirety.

### FIELD

The present disclosure relates generally to tape and reel packages, and more particularly to carrier tapes with more than one row of cavities for cost saving.

### BACKGROUND

Surface mount technology (SMT) is the process wherein electrical components are mounted onto a surface of a printed circuit board (PCB). The PCB may contain any number of unique electrical components, as well as any number of identical electrical components. These electrical components are often placed on the surface of the PCB using pick and place machinery. Each electrical component can be loaded into the pick and place machinery using tape and reel packages. The tape and reel packages can hold a plurality of electrical components in pockets generally aligned along a length of a carrier tape. A cover tape can be adhered to a top surface of the carrier tape to seal the carrier tape. The sealed carrier tape can be wound around a reel. The reel can then be packed into packaging containers for shipping.

### SUMMARY

This summary is provided to introduce a selection of disclosed concepts in a simplified form that are further described below in the detailed description including the drawings provided. This summary is not intended to limit the scope of the claimed subject matter.

Disclosed aspects include a carrier tape. The carrier tape comprises a carrier tape length and a carrier tape width. The carrier tape also comprises a plurality of holes spaced along the carrier tape length. The carrier tape further comprises a first cavity and a second cavity. The first cavity and the second cavity are spaced along the carrier tape width.

Disclosed aspects include a package. The package comprises a carrier tape. The carrier tape comprises a carrier tape length and a carrier tape width. The carrier tape also comprises a plurality of holes spaced along the carrier tape length. The carrier tape further comprises a first cavity and a second cavity. The first cavity and the second cavity are spaced along the carrier tape width. The package also comprises a first component in the first cavity and a second component in the second cavity. The package further comprises a cover tape on the carrier tape covering the first cavity and the second cavity.

Disclosed aspects include a method. The method comprises picking a first component from a first cavity on a carrier tape. The carrier tape comprises a carrier tape length, a carrier tape width, and a plurality of holes spaced along the carrier tape length. The method also comprises picking a second component from a second cavity on the carrier tape. The first cavity and the second cavity are spaced along the carrier tape width.

Disclosed aspects include a method. The method comprises placing a first component in a first cavity on a carrier tape. The carrier tape comprises a carrier tape length, a carrier tape width, and a plurality of holes spaced along the carrier tape length. The method also comprises placing a second component in a second cavity on the carrier tape. The first cavity and the second cavity are spaced along the carrier tape width.

### BRIEF DESCRIPTION OF THE DRAWINGS

Reference will now be made to the accompanying drawings, which are not necessarily drawn to scale, wherein:

FIG. 1A is a top view of a carrier tape with a single row of cavities;

FIG. 1B is a cross-section view of the carrier tape of FIG. 1A;

FIG. 2A is a top view of an example carrier tape with three rows of cavities in accordance with certain aspects of present disclosure;

FIG. 2B is a top view of another example carrier tape with three rows of cavities in accordance with certain aspects of present disclosure;

FIG. 3A is a top view of an example carrier tape with three rows of cavities having a line shape sealing area between cavities in accordance with certain aspects of present disclosure;

FIG. 3B is a top view of an example carrier tape with three rows of cavities having a dot shape sealing area between cavities in accordance with certain aspects of present disclosure;

FIG. 4 illustrates dimensions for an example carrier tape with three rows of cavities in accordance with certain aspects of present disclosure;

FIGS. 5A-5D illustrate top views of examples of carrier tapes with more than one row of cavities in accordance with certain aspects of present disclosure;

FIG. 6. is a cross-section view of an example package using a carrier tape with more than one row of cavities in accordance with certain aspects of present disclosure;

FIG. 7. Illustrates a process for picking components from an example carrier tape with more than one row of cavities in accordance with certain aspects of present disclosure; and

FIG. 8. Illustrates a process for placing components on an example carrier tape with more than one row of cavities in accordance with certain aspects of present disclosure.

### DETAILED DESCRIPTION

In the drawings, like reference numerals refer to like elements throughout, and the various features are not necessarily drawn to scale. Also, the term “couple” or “couples” includes indirect or direct electrical or mechanical connection or combinations thereof. For example, if a first device couples to or is coupled with a second device, that connection may be through a direct electrical connection, or through an indirect electrical connection via one or more intervening devices and connections. One or more operational characteristics of various circuits, systems and/or components are hereinafter described in the context of functions which in some cases result from configuration and/or interconnection of various structures when circuitry is powered and operating. In the following discussion and in the claims, the terms “including,” “includes,” “having,” “has,” “with,” or variants thereof are intended to be inclusive in a manner similar to the term “comprising,” and thus should be interpreted to mean “including, but not limited to.”

Unless otherwise stated, “about,” “approximately,” or “substantially” preceding a value means +/−10 percent of the stated value. One or more structures, features, aspects, components, etc., may be referred to herein as first, second, third, etc., such as first and second terminals, first, second, and third dies, etc., for ease of description in connection with a particular drawing, where such are not to be construed as limiting with respect to the claims. Various disclosed structures and methods of the present disclosure may be beneficially applied to manufacturing a semiconductor device such as an integrated circuit. While such examples may be expected to provide various improvements, no particular result is a requirement of the present disclosure unless explicitly recited in a particular claim.

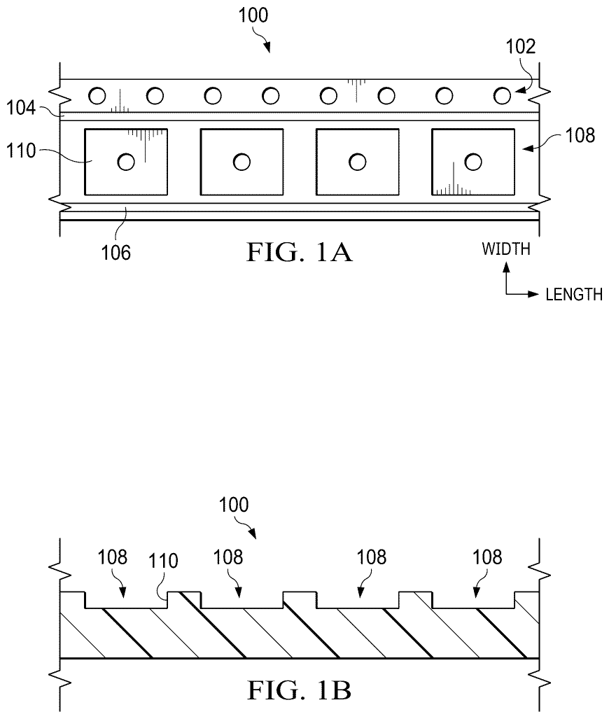

Electrical components may be produced in one factory and assembled onto printed circuit boards (PCBs) in another factory. At the assembly site, many unique electrical components from many different factories may be mounted onto PCBs to create an electric product. The assembly site may employ automated machinery to move the electrical components from packaging material they are shipped in onto the PCBs. The packaging material may include a tape and reel package having a reel with carrier tape spooled around it. The carrier tape may contain cavities that hold the electrical components and are covered with cover tape to seal the electrical components in the cavities. FIG. 1A is a top view of a carrier tape 100 with a single row of cavities that can be used for tape and reel packages mentioned above. The carrier tape 100 comprises a plurality of holes 102 along a first edge of the carrier tape 100. The plurality of holes 102 may align with sprockets of a wheel in the automated machinery. The wheel may be used to progress the carrier tape 100 and unspool it from the reel. The carrier tape 100 also comprises a first sealing area 104 adjacent the plurality of holes 102 and a second sealing area 106 along a second edge of the carrier tape 100. The first sealing area 104 and the second sealing area 106 are used to adhere the carrier tape 100 to a cover tape (not shown). The cover tape may not cover the plurality of holes 102. The carrier tape 100 further comprises a plurality of cavities 108. The plurality of cavities 108 are arranged in a single row along a length of the carrier tape 100. The plurality of cavities 108 include a first cavity 110. The first cavity 110 can be used to hold an electrical component on the carrier tape 100. Each cavity of the plurality of cavities 108 includes a hole at a bottom of the cavity. FIG. 1B is a cross-section view of the carrier tape 100 of FIG. 1A. The carrier tape 100 may be made of polycarbonate, polystyrene, or any other suitable material. As the number of electrical components in each electric product keeps increasing, more packaging material would be used for tape and reel packages. There is a need for more cost-effective package material design.

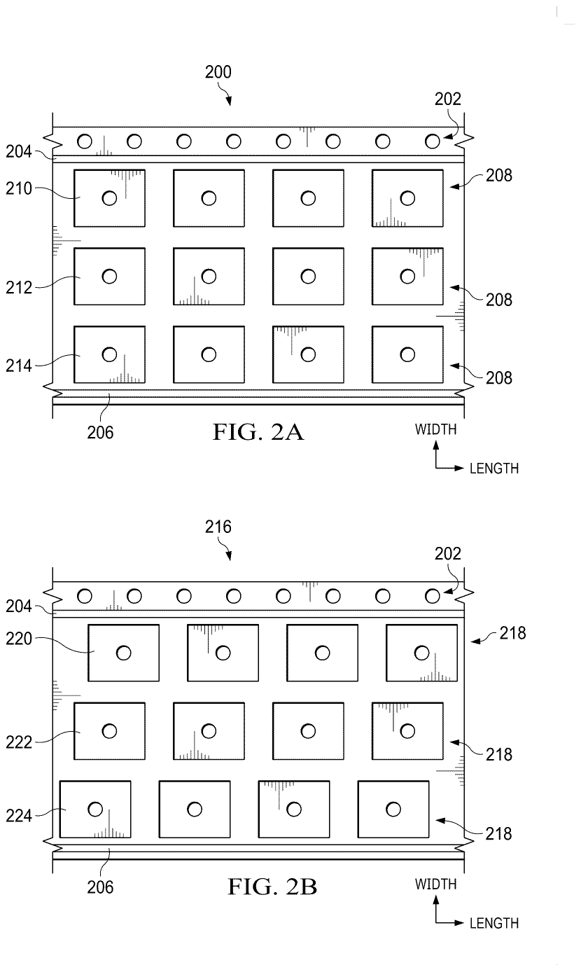

Disclosed aspects include a carrier tape with more than one row of cavities. FIG. 2A is a top view of a carrier tape 200 with three rows of cavities in accordance with certain aspects of present disclosure. The carrier tape 200 comprises a plurality of holes 202 along a first edge of the carrier tape 200. The plurality of holes 202 may align with sprockets of a wheel in the automated machinery. The wheel may be used to progress the carrier tape 200 and unspool it from the reel. The carrier tape 200 also comprises a first sealing area 204 adjacent the plurality of holes 202 and a second sealing area 206 along a second edge of the carrier tape 200. The first sealing area 204 and the second sealing area 206 are used to adhere the carrier tape 200 to a cover tape (not shown). The cover tape may not cover the plurality of holes 202. The carrier tape 200 further comprises a plurality of cavities 208. The plurality of cavities 208 are arranged in three rows along a length of the carrier tape 200. The carrier tape 200 comprising three rows of cavities is shown as an example. The carrier tape 200 may comprise any number of rows of cavities. The plurality of cavities 208 include a first cavity 210 in a first row, a second cavity 212 in a second row, and a third cavity 214 in a third row. The first cavity 210, the second cavity 212, and the third cavity 214 can be used to hold electrical components on the carrier tape 200. A center of the first cavity 210, a center of the second cavity 212, and a center of the third cavity 214 may be aligned along a width of the carrier tape 200. Each cavity of the plurality of cavities 208 includes a hole at a bottom of the cavity. FIG. 2B is a top view of a carrier tape 216 with three rows of cavities in accordance with certain aspects of present disclosure. Most features of the carrier tape 216 are similar to the carrier tape 200. The carrier tape 216 comprises a plurality of cavities 218. The plurality of cavities 218 are arranged in three rows along a length of the carrier tape 216. The carrier tape 216 comprising three rows of cavities is shown as an example. The carrier tape 216 may comprise any number of rows of cavities. The plurality of cavities 218 include a first cavity 220 in a first row, a second cavity 222 in a second row, and a third cavity 224 in a third row. The first cavity 220, the second cavity 222, and the third cavity 224 can be used to hold electrical components on the carrier tape 216. A center of the first cavity 220, a center of the second cavity 222, and a center of the third cavity 224 may not be aligned along a width of the carrier tape 216. Each cavity of the plurality of cavities 218 includes a hole at a bottom of the cavity.

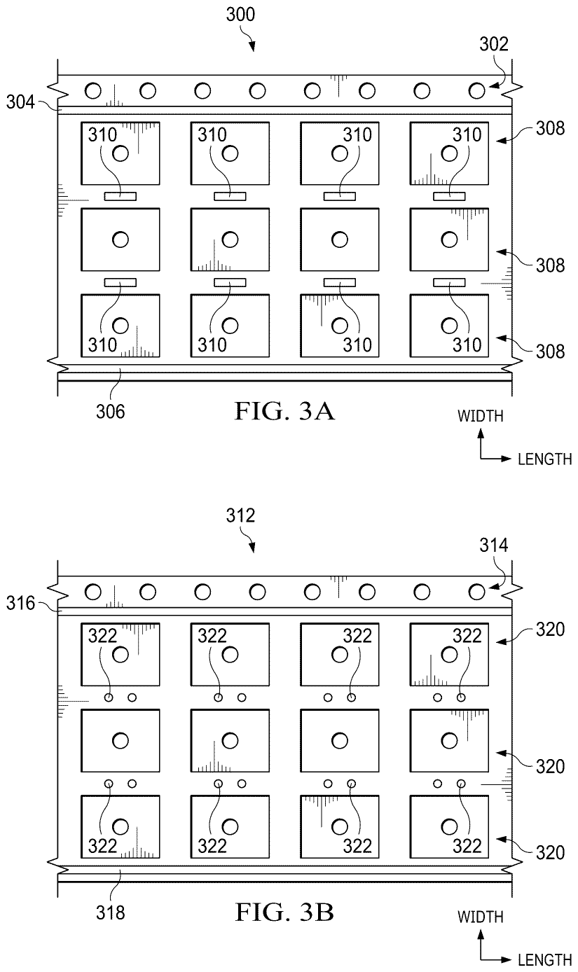

FIG. 3A is a top view of a carrier tape 300 with three rows of cavities having a line shape sealing area between cavities in accordance with certain aspects of present disclosure. The carrier tape 300 is similar to the carrier tape 200. The carrier tape 300 comprises a plurality of holes 302 along a first edge of the carrier tape 300. The carrier tape 300 also comprises a first sealing area 304 adjacent the plurality of holes 302 and a second sealing area 306 along a second edge of the carrier tape 300. The carrier tape 300 also comprises a plurality of cavities 308. The plurality of cavities 308 are arranged in three rows along a length of the carrier tape 300. The carrier tape 300 comprising three rows of cavities is shown as an example. The carrier tape 300 may comprise any number of rows of cavities. The carrier tape 300 further comprises a plurality of sealing areas 310 between cavities in different rows. The plurality of sealing areas 310 may have a line shape. The plurality of sealing areas 310, together with the first sealing area 304 and the second sealing area 306, are used to adhere the carrier tape 300 to a cover tape (not shown). The cover tape may not cover the plurality of holes 302. FIG. 3B is a top view of a carrier tape 312 with three rows of cavities having a dot shape sealing area between cavities in accordance with certain aspects of present disclosure. The carrier tape 312 is similar to the carrier tape 200. The carrier tape 312 comprises a plurality of holes 314 along a first edge of the carrier tape 312. The carrier tape 312 also comprises a first sealing area 316 adjacent the plurality of holes 314 and a second sealing area 318 along a second edge of the carrier tape 312. The carrier tape 312 also comprises a plurality of cavities 320. The plurality of cavities 320 are arranged in three rows along a length of the carrier tape 312. The carrier tape 312 comprising three rows of cavities is shown as an example. The carrier tape 312 may comprise any number of rows of cavities. The carrier tape 312 further comprises a plurality of sealing areas 322 between cavities in different rows. The plurality of sealing areas 322 may have a dot shape. The plurality of sealing areas 322, together with the first sealing area 316 and the second sealing area 318, are used to adhere the carrier tape 312 to a cover tape (not shown). The cover tape may not cover the plurality of holes 314. The plurality of sealing areas 310 and 322 can have any suitable shape for adhering the carrier tape 300 and 312 to the cover tape.

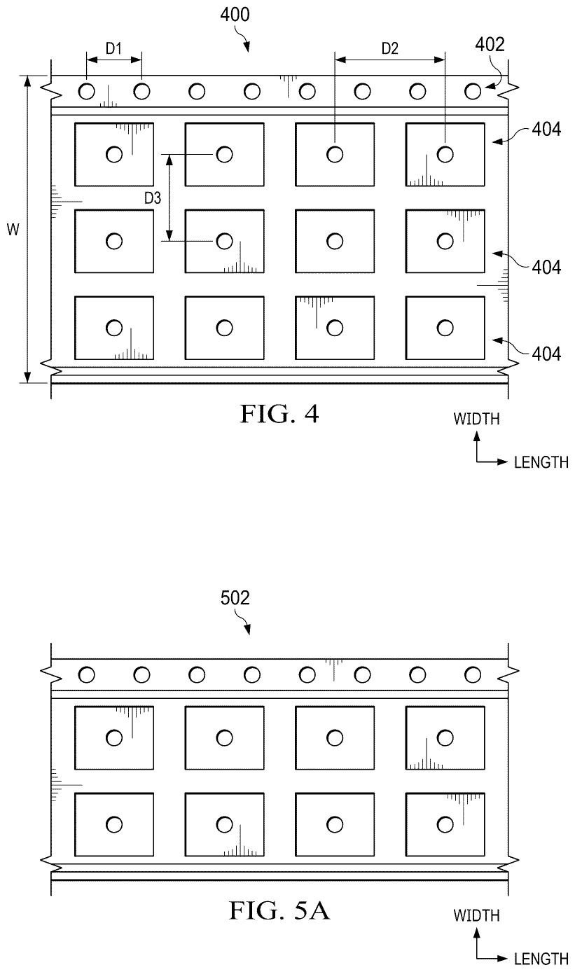

FIG. 4 illustrates some example dimensions for a carrier tape 400 with three rows of cavities in accordance with certain aspects of present disclosure. The carrier tape 400 is similar to the carrier tape 200. The carrier tape 400 comprises a plurality of holes 402 along a first edge of the carrier tape 400. Each hole of the plurality of holes 402 may be circular and have a diameter of about 1.5 mm. A distance D1 from center to center of adjacent holes may be 4 mm. The carrier tape 400 further comprises a plurality of cavities 404. The plurality of cavities 404 are arranged in three rows along a length of the carrier tape 400. Each cavity of the plurality of cavities 404 may be designed to allow an electrical component inside the cavity to rotate 20 degrees or less in a top view. A length and a width of each cavity may be designed to allow an electrical component inside the cavity to move 1 mm or less laterally. A depth of each cavity may be designed to ensure a top surface of an electrical component inside the cavity does not protrude above a top surface of the carrier tape 400 and to allow the electrical component to rotate 20 degrees or less in a side view. A distance D2 from center to center of adjacent cavities along the length of the carrier tape 400 may be 2 mm, 4 mm, or a multiple of 4 mm. A distance D3 from center to center of adjacent cavities along a width of the carrier tape 400 may be 6.25 mm. D3 may depend on size and package type of electrical components inside the plurality of cavities 404. The width (W) of the carrier tape 400 may be 8 mm, 12 mm, or other increments of 4 mm. The dimensions of the carrier tape 400 shown in FIG. 4 are examples. Other dimensions are possible based on different applications of the carrier tape 400.

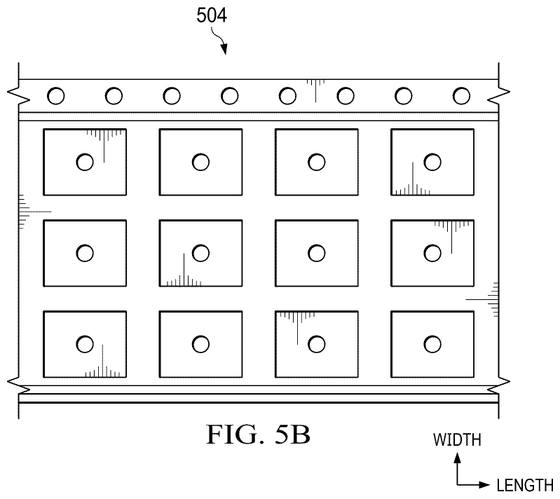

FIGS. 5A-5D illustrate top views of carrier tapes with more than one row of cavities in accordance with certain aspects of present disclosure. In FIG. 5A, carrier tape 502 has two rows of cavities along a length of the carrier tape 502. The carrier tape 502 may hold 5000 electrical components per reel. In FIG. 5B, carrier tape 504 has three rows of cavities along a length of the carrier tape 504. The carrier tape 504 may hold 7500 electrical components per reel. In FIG. 5C, carrier tape 506 has four rows of cavities along a length of the carrier tape 506. The carrier tape 506 may hold 6664 electrical components per reel. In FIG. 5D, carrier tape 508 has five rows of cavities along a length of the carrier tape 508. The carrier tape 508 may hold 8330 electrical components per reel. Orientations of cavities on the carrier tape 502, 504, 506, and 508 may be different. In some implementations, a length of a cavity aligns with the length of the carrier tape. In other implementations, a width of a cavity aligns with the length of the carrier tape. For the carrier tapes 506 and 508, they comprise a first plurality of holes along a first edge and a second plurality of holes along a second edge. The first plurality of holes and the second plurality of holes may have same (e.g., circular) or different (e.g., circular and oval) shapes. With more than one row of cavities on a carrier tape, more electrical components can be placed per reel, which could save packaging material and improve SMT efficiency.

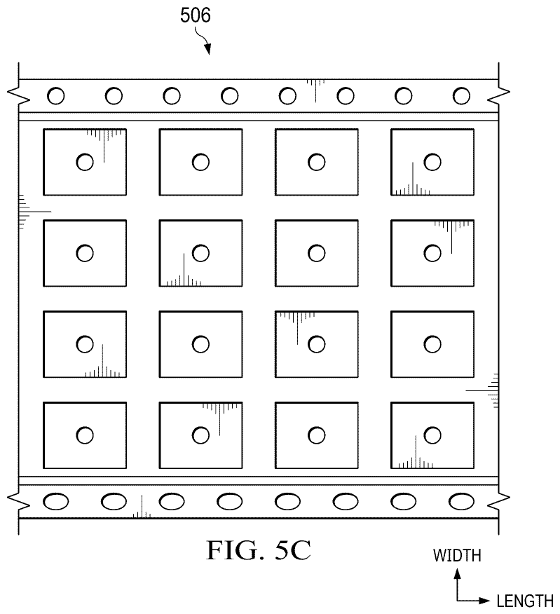

FIG. 6 is a cross-section view of a package 600 using a carrier tape 602 with more than one row of cavities in accordance with certain aspects of present disclosure. The package 600 comprises the carrier tape 602 and a cover tape 604 on the carrier tape 602. The carrier tape 602 may be similar to the carrier tape 200, 216, 300, 312, 502, 504, 506, and 508. The carrier tape 602 comprises a plurality of cavities 606. Each cavity of the plurality of cavities 606 contains an electrical component 608 inside the cavity. The cover tape 604 seals the electrical component 608 in each cavity. The electrical component 608 in each cavity may be same or different electrical components. The package 600 can be spooled around a reel and form a tape and reel package.

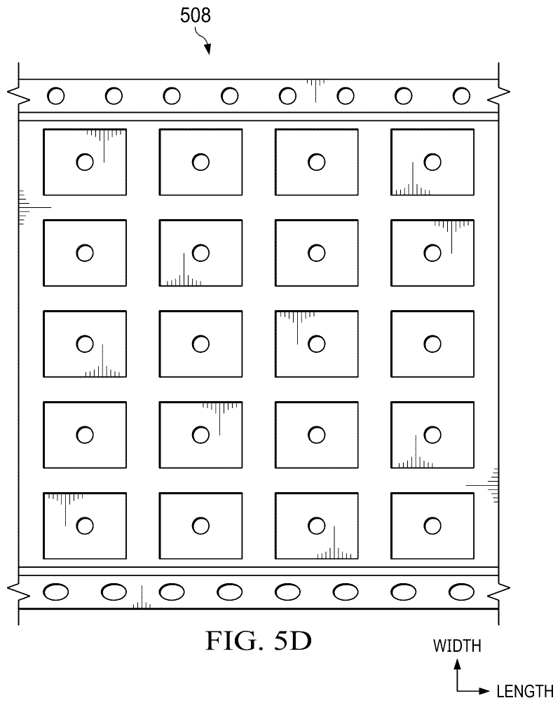

FIG. 7 illustrates a process 700 for picking components from a carrier tape with more than one row of cavities in accordance with certain aspects of present disclosure. Step 702 includes picking a first component from a first cavity on a carrier tape. The carrier tape comprises more than one row of cavities along a length of the carrier tape. The first cavity is in a first row. Step 704 includes picking a second component from a second cavity on the carrier tape. The second cavity is in a second row. The first row and the second row are spaced along a width of the carrier tape. The first component and the second component may be picked in sequence or simultaneously. The process 700 may include picking a third component from a third cavity on the carrier tape. The third cavity is in a third row. The first row, the second row, and the third row are spaced along the width of the carrier tape. The first component, the second component, and the third component may be picked in sequence or simultaneously. The process 700 may also include moving the carrier tape along the length of the carrier tape and picking a fourth component from a fourth cavity on the carrier tape. The fourth cavity is in the third row. The process 700 may further include picking a fifth component from a fifth cavity on the carrier tape. The fifth cavity is in the second row. The fourth component and the fifth component may be picked in sequence or simultaneously. The process 700 may alternatively include after picking the second component, moving the carrier tape along the length of the carrier tape and picking a third component from a third cavity on the carrier tape. The third cavity is in the second row. The process 700 may also include picking a fourth component from a fourth cavity on the carrier tape. The fourth cavity is in the first row. The third component and the fourth component may be picked in sequence or simultaneously. The process 700 may further include moving the carrier tape along the length of the carrier tape and picking a fifth component from a fifth cavity on the carrier tape. The fifth cavity is in the first row. The process 700 would continue to pick components based on design of the carrier tape.

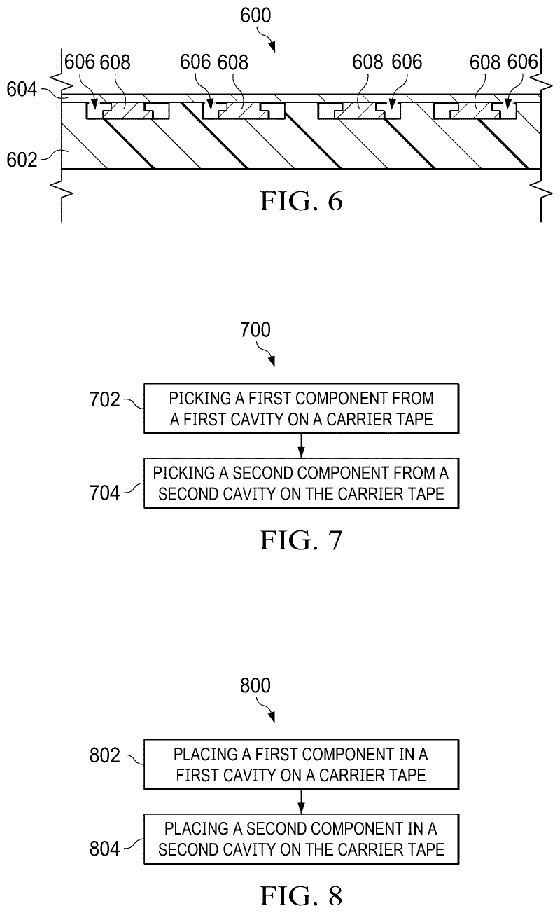

FIG. 8 illustrates a process 800 for placing components on a carrier tape with more than one row of cavities in accordance with certain aspects of present disclosure. Step 802 includes placing a first component in a first cavity on a carrier tape. The carrier tape comprises more than one row of cavities along a length of the carrier tape. The first cavity is in a first row. Step 804 includes placing a second component in a second cavity on the carrier tape. The second cavity is in a second row. The first row and the second row are spaced along a width of the carrier tape. The first component and the second component may be placed in sequence or simultaneously. The process 800 may include placing a third component in a third cavity on the carrier tape. The third cavity is in a third row. The first row, the second row, and the third row are spaced along the width of the carrier tape. The first component, the second component, and the third component may be placed in sequence or simultaneously. The process 800 may also include moving the carrier tape along the length of the carrier tape and placing a fourth component in a fourth cavity on the carrier tape. The fourth cavity is in the third row. The process 800 may further include placing a fifth component in a fifth cavity on the carrier tape. The fifth cavity is in the second row. The fourth component and the fifth component may be placed in sequence or simultaneously. The process 800 may alternatively include after placing the second component, moving the carrier tape along the length of the carrier tape and placing a third component in a third cavity on the carrier tape. The third cavity is in the second row. The process 800 may also include placing a fourth component in a fourth cavity on the carrier tape. The fourth cavity is in the first row. The third component and the fourth component may be placed in sequence or simultaneously. The process 800 may further include moving the carrier tape along the length of the carrier tape and placing a fifth component in a fifth cavity on the carrier tape. The fifth cavity is in the first row. The process 800 would continue to place components based on design of the carrier tape. After placing all the components, the process 800 would continue with covering the carrier tape with a cover tape.

Those skilled in the art to which this disclosure relates will appreciate that many variations of disclosed aspects are possible within the scope of the claimed invention, and further additions, deletions, substitutions, and modifications may be made to the above-described aspects without departing from the scope of this disclosure.

What is claimed is:

1. A carrier tape, comprising:
a carrier tape length;
a carrier tape width;
a plurality of holes spaced along the carrier tape length;
a first cavity; and
a second cavity, wherein the first cavity and the second cavity are spaced along the carrier tape width.

2. The carrier tape of claim 1, wherein a center of the first cavity and a center of the second cavity are aligned along the carrier tape width.

3. The carrier tape of claim 1, wherein a center of the first cavity and a center of the second cavity are not aligned along the carrier tape width.

4. The carrier tape of claim 1, further comprising a third cavity, wherein the first cavity, the second cavity, and the third cavity are spaced along the carrier tape width.

5. The carrier tape of claim 1, further comprising a fourth cavity, wherein the first cavity and the fourth cavity are spaced along the carrier tape length.

6. The carrier tape of claim 5, wherein a center of the first cavity and a center of the second cavity are spaced apart by a first distance along the carrier tape width, the center of the first cavity and a center of the fourth cavity are spaced apart by a second distance along the carrier tape length, and the first distance is different from the second distance.

7. The carrier tape of claim 1, further comprising a first sealing area adjacent the plurality of holes along the carrier tape length.

8. The carrier tape of claim 7, further comprising a second sealing area between the first cavity and the second cavity.

9. The carrier tape of claim 8, wherein the second sealing area comprises a line shape or a dot shape.

10. A package, comprising:
a carrier tape, the carrier tape comprising a carrier tape length; a carrier tape width; a plurality of holes spaced along the carrier tape length; a first cavity; and a second cavity, wherein the first cavity and the second cavity are spaced along the carrier tape width;
a first component in the first cavity;
a second component in the second cavity; and
a cover tape on the carrier tape covering the first cavity and the second cavity.

11. The package of claim 10, wherein a center of the first cavity and a center of the second cavity are aligned along the carrier tape width.

12. The package of claim 10, wherein a center of the first cavity and a center of the second cavity are not aligned along the carrier tape width.

13. The package of claim 10, wherein the carrier tape further comprises a third cavity, and wherein the first cavity and the third cavity are spaced along the carrier tape length.

14. The package of claim 13, wherein a center of the first cavity and a center of the second cavity are spaced apart by a first distance along the carrier tape width, the center of the first cavity and a center of the third cavity are spaced apart by a second distance along the carrier tape length, and the first distance is different from the second distance.

15. The package of claim 10, wherein the carrier tape further comprises a first sealing area adjacent the plurality of holes along the carrier tape length.

16. The package of claim 15, wherein the carrier tape further comprises a second sealing area between the first cavity and the second cavity.

17. The package of claim 16, wherein the second sealing area comprises a line shape or a dot shape.

18. A method, comprising:
picking a first component from a first cavity on a carrier tape, the carrier tape comprising a carrier tape length; a carrier tape width; and a plurality of holes spaced along the carrier tape length; and
picking a second component from a second cavity on the carrier tape, wherein the first cavity and the second cavity are spaced along the carrier tape width.

19. The method of claim 18, further comprising picking a third component from a third cavity on the carrier tape, wherein the first cavity, the second cavity, and the third cavity are spaced along the carrier tape width.

20. The method of claim 19, further comprising moving the carrier tape along the carrier tape length; and picking a fourth component from a fourth cavity on the carrier tape, wherein the third cavity and the fourth cavity are spaced along the carrier tape length.

21. The method of claim 18, further comprising moving the carrier tape along the carrier tape length; and picking a fifth component from a fifth cavity on the carrier tape, wherein the second cavity and the fifth cavity are spaced along the carrier tape length.

22. The method of claim 21, further comprising picking a sixth component from a sixth cavity on the carrier tape, wherein the fifth cavity and the sixth cavity are spaced along the carrier tape width.

23. The method of claim 18, wherein a center of the first cavity and a center of the second cavity are aligned along the carrier tape width.

24. The method of claim 18, wherein a center of the first cavity and a center of the second cavity are not aligned along the carrier tape width.

25. A method, comprising:
placing a first component in a first cavity on a carrier tape, the carrier tape comprising a carrier tape length; a carrier tape width; and a plurality of holes spaced along the carrier tape length; and
placing a second component in a second cavity on the carrier tape, wherein the first cavity and the second cavity are spaced along the carrier tape width.

26. The method of claim 25, further comprising covering the first cavity and the second cavity using a cover tape.

27. The method of claim 25, further comprising placing a third component in a third cavity on the carrier tape, wherein the first cavity, the second cavity, and the third cavity are spaced along the carrier tape width.

28. The method of claim 25, further comprising moving the carrier tape along the carrier tape length; and placing a fourth component in a fourth cavity on the carrier tape, wherein the second cavity and the fourth cavity are spaced along the carrier tape length.

29. The method of claim 25, wherein a center of the first cavity and a center of the second cavity are aligned along the carrier tape width.

30. The method of claim 25, wherein a center of the first cavity and a center of the second cavity are not aligned along the carrier tape width.
